(19) United States
(12) Patent Application Publication
(10) Pub. No.: US 2017/0344688 A1
(43) Pub. Date: Nov. 30, 2017

(54) COMPONENT PLACEMENT METHOD AND INFORMATION PROCESSING APPARATUS

(71) Applicant: FUJITSU LIMITED, Kawasaki-shi (JP)

(72) Inventors: Kazuhiro SAKAI, Kawasaki (JP); Masato ARIYAMA, Kawasaki (JP); Kenichi NISHIMURA, Kawasaki (JP); Akira MIMURA, Kawasaki (JP); Yusuke KIMURA, Kawasaki (JP)

(73) Assignee: FUJITSU LIMITED, Kawasaki-shi (JP)

(21) Appl. No.: 15/479,712

(22) Filed: Apr. 5, 2017

(30) Foreign Application Priority Data
May 27, 2016 (JP) 2016-106478

(51) Int. Cl. G06F 17/50; H05K 1/18

(52) U.S. Cl. CPC G06F 17/5072; H05K 1/18

(57) ABSTRACT

A processor of an information processing apparatus displays a first component in a state in which a first terminal of the first component is located on a second terminal of a second component. The processor displays, along a designated route, a first wiring pattern for connecting the second terminal to the first terminal and moves the first component to a first distal end of the first wiring pattern. The processor determines whether a pattern area of the first wiring pattern or a component area of the first component which is placed at a second distal end of the designated route overlaps any of first areas of already placed components or second areas of already wired wiring patterns. The processor finalizes placement of the first component and the first wiring pattern upon determining that the pattern area and the component area overlap none of the first areas and the second areas.

### CROSS-REFERENCE TO RELATED APPLICATION

This application is based upon and claims the benefit of priority of the prior Japanese Patent Application No. 2016-106478, filed on May 27, 2016, the entire contents of which are incorporated herein by reference.

### FIELD

The embodiment discussed herein is related to a component placement method and an information processing apparatus.

### BACKGROUND

Typically, when designing component placement and pattern wiring on a printed circuit board for an electronic equipment/device, major components such as a large-scale integration (LSI) and an integrated circuit (IC) are first placed, and then the placement and pattern wiring for sub-components such as a resistor and a capacitor are performed.

As a related technique, there is a technique in which, in a method for automatically determining placement and wiring for a printed circuit board, a pre-designated pair of components is displayed in a highlighted manner and is wired prior to other components. Also, as a related technique, there is a technique in which, in an apparatus for aiding placement and design of components on a printed circuit board, surface-mounted components, such as a chip resistor, are placed so that they do not overlap placement-prohibited areas.

Related techniques are disclosed in, for example, Japanese Laid-open Patent Publication No. 9-50456 and Japanese Laid-open Patent Publication No. 2007-140679.

During design of component placement and pattern wiring on a printed circuit board, there are cases in which the number of wiring channels becomes insufficient owing to concentration of components and an increased density of wiring. In such cases, during design of component placement and pattern wiring, for example, an already placed component may be moved to a position where wiring becomes possible or a wiring pattern may be re-rerouted or moved. Thus, there is a problem in that rework often occurs during the design of the component placement and pattern wiring.

### SUMMARY

According to an aspect of the present invention, provided is an information processing apparatus including a memory and a processor coupled to the memory. The processor is configured to display, when a first component is not yet placed on a printed circuit board to be designed in a simulation space, the first component in a first state in which a first terminal of the first component is located on a second terminal of a second component. The second terminal has a connection relationship with the first terminal. The second component is included in already placed components which are already placed on the printed circuit board. The processor is configured to display a first wiring pattern along a designated route. The first wiring pattern is to connect the second terminal to the first terminal. The processor is configured to re-display the first component in a state in which the first terminal is located at a first distal end of the first wiring pattern. The processor is configured to determine whether a pattern area of the first wiring pattern overlaps any of first areas of the already placed components or second areas of already wired wiring patterns. The processor is configured to determine, upon receiving an instruction for finalizing the designated route, whether a component area of the first component which is placed at a second distal end of the designated route overlaps any of the first areas or the second areas. The processor is configured to finalize placement of the first component at the second distal end and finalize the first wiring pattern, when it is determined that the pattern area overlaps none of the first areas and the second areas and the component area overlaps none of the first areas and the second areas.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an exemplary operation of an information processing apparatus according to an embodiment;

FIG. 2 is a diagram illustrating an example of component movement and wiring owing to congestion of wiring channels;

FIG. 3 is a diagram illustrating an exemplary hardware configuration of an information processing apparatus;

FIG. 4 is a diagram illustrating an exemplary functional configuration of an information processing apparatus;

FIG. 5 is a diagram illustrating an exemplary data structure of a net connection table;

FIG. 6 is a diagram illustrating an exemplary data structure of a component placement table;

FIG. 7 is a diagram illustrating an exemplary data structure of an obstacle management table;

FIG. 8 is a diagram illustrating an exemplary data structure of a wiring-pattern table;

FIG. 9 is a diagram illustrating an exemplary data structure of a component shape library;

FIG. 10 is a diagram illustrating an exemplary data structure of a component-pin shape library;

FIG. 11 is a diagram illustrating an exemplary data structure of an adjacent-element acquisition table;

FIG. 12 is a diagram illustrating a first wiring example;

FIG. 13 is a diagram illustrating a second wiring example;

FIG. 14 is a diagram illustrating an exemplary display of an unplaced component;

FIG. 15 is a diagram illustrating an exemplary display of an unplaced component in a plurality of orientations;

FIG. 16 is a diagram illustrating an exemplary definition of orientations based on a polarity;

FIG. 17 is a diagram illustrating an exemplary display of an unplaced component in orientations based on a polarity thereof;

FIG. 18 is a diagram illustrating an example of a wiring pattern between already placed components;

FIG. 19 is a diagram illustrating an example of a wiring pattern between already placed components;

FIGS. 20A and 20B diagrams illustrating examples of component placement work and wiring work of related art as comparative examples;

FIG. 20C is a diagram illustrating an example of component placement work and wiring work performed by an information processing apparatus according to an embodiment;

FIG. 21 is a flowchart illustrating an exemplary procedure of component placement processing performed by an information processing apparatus according to an embodiment;

FIG. 22 is a flowchart illustrating an exemplary procedure of processing for placing and wiring a later-placed component, performed by an information processing apparatus according to an embodiment;

FIG. 23 is a flowchart illustrating an exemplary procedure of processing for placing and wiring a later-placed component, performed by an information processing apparatus according to an embodiment; and

FIG. 24 is a flowchart illustrating an exemplary procedure of processing for placing and wiring a later-placed component, performed by an information processing apparatus according to an embodiment.

### DESCRIPTION OF EMBODIMENT

A component placement method and an information processing apparatus according to an embodiment will be described below in detail with reference to the accompanying drawings.

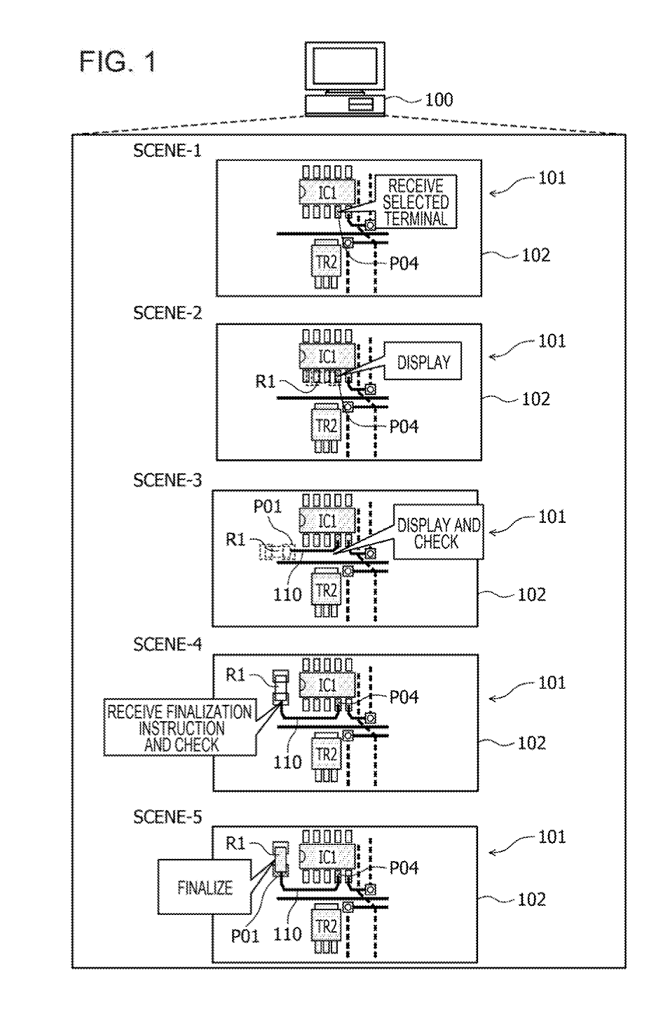

FIG. 1 is a diagram illustrating an exemplary operation of an information processing apparatus according to an embodiment. An information processing apparatus 100 is a computer that connects, on a printed circuit board 102 to be designed in a simulation space 101, an unplaced first component to an already placed second component with a wiring pattern and finalizes the placement. The information processing apparatus 100 is a computer that executes a computer-aided design (CAD) capable of designing the printed circuit board 102.

The simulation space 101 is a virtual space simulated on the computer. Specifically, for example, the simulation space 101 is a space virtually set in the information processing apparatus 100 in order to design the printed circuit board 102. For example, a global coordinate system having an X-axis and a Y-axis is defined in the simulation space 101.

Before the printed circuit board 102 is designed, the shapes, polarity definitions, and so on of components and pins of the components are prepared as various libraries. The components and the pins of the components are designed in respective simulation spaces 101. For example, a local coordinate system having an X-axis and a Y-axis is defined in the respective simulation spaces 101.

Heretofore, when designing component placement and pattern wiring on a printed circuit board 102 for an electronic equipment/device, major components such an LSI and an IC are first placed, and then sub-components such as a transistor and a resistor are placed. For placement of the sub-components, two-terminal components such as a two-terminal resistor and a two-terminal capacitor are, in many cases, placed in the last half of the placement work. Thus, the sub-components are placed so as to fill the gap between already placed components. After various types of components are placed, pattern wiring is performed to provide connections between component pins of the various types of components. In many cases, in the wiring work, as in the placement work, the major components are wired first, and the sub-components are wired in the last half of the wiring work.

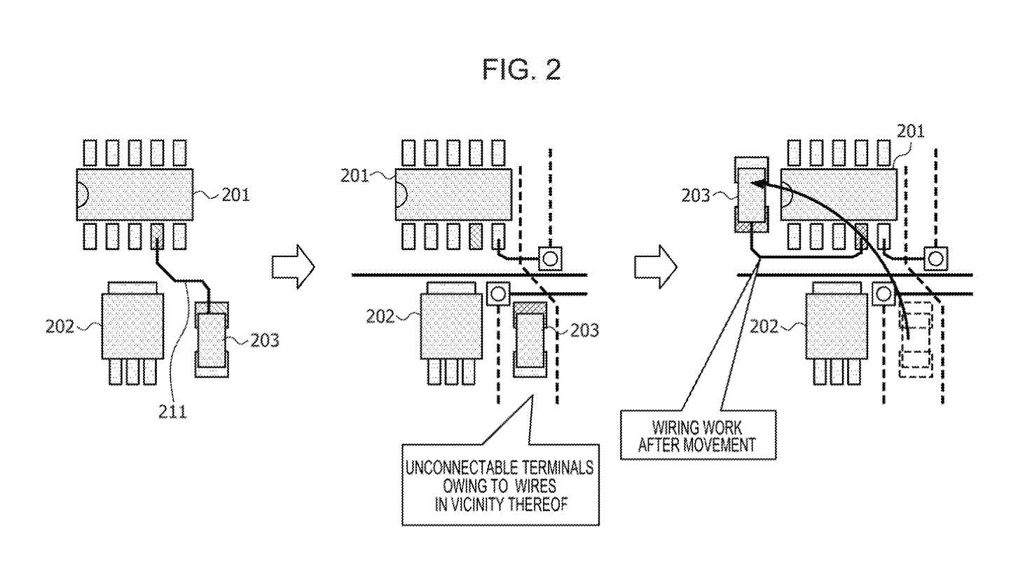

There are cases in which the number of wiring channels becomes insufficient owing to concentration of components and an increased density of wiring. The “wiring channel” refers to a wiring path through which a wiring pattern provided between components may be passed. In particular, there are cases in which, toward the end of the wiring work, the number of wiring channels becomes insufficient owing to concentration of components and an increased density of wiring. In such cases, during design of component placement and pattern wiring, for example, an already placed component is moved to a position where wiring becomes possible, a wiring pattern is re-routed, or a wiring pattern is moved, as described later with reference to FIG. 2. Thus, design work for component placement and pattern wiring has a problem in that rework for the design often occurs.

Accordingly, during wiring work for a wiring pattern starting from an already placed component to connect an unplaced component, when an area of the unplaced component that is temporarily placed at a distal end of the wiring pattern and an area of the wiring pattern do not interfere with areas of already placed and wired elements, the information processing apparatus 100 finalizes the component placement and the wiring pattern. This makes it possible to perform placement work for an unplaced component while performing wiring work, thus making it possible to reduce redoing of the placement work and the wiring work.

The information processing apparatus 100 displays, on the printed circuit board 102, an unplaced first component in a state in which a first terminal of the first component is located on a second terminal of an already placed second component having a connection relationship with the first terminal.

As illustrated in SCENE-1 in FIG. 1, a component IC1 and a component TR2 are already placed. The information processing apparatus 100 receives a selected second terminal of an already placed second component. In the example illustrated in FIG. 1, the second component is the component IC1, which is a major component. The second terminal is a pin P04 of the component IC1. In the example illustrated in FIG. 1, the first component is a two-terminal component R1, which is a sub-component. The first terminal is a pin P01 of the component R1.

As illustrated in SCENE-2 in FIG. 1, the information processing apparatus 100 displays the component R1 in a state in which the pin P01 of the component R1 is located on the selected pin P04. The information processing apparatus 100 displays the unplaced component R1 such that it may be distinguished from the already placed components IC1 and TR2. In order to distinguish the unplaced component R1 from the already placed components IC1 and TR2, the information processing apparatus 100 varies the display color, the display line type, the display line width, and so on between the unplaced component R1 and the already placed components IC1 and TR2. In the example illustrated in FIG. 1, the line type for the component R1 is a dashed line, and the line type for the already placed component IC1 and TR2 is a solid line. With respect to the component R1, only the outer shape thereof is displayed with a dashed line.

Next, the information processing apparatus 100 displays a first wiring pattern that connects from the second terminal to the first terminal, along a route designated from the second terminal. The “designated route” means, for example, a route of the first wiring pattern, which is designated by a designer's operation. In the example illustrated in FIG. 1, the first wiring pattern is a wiring pattern 110. As illustrated in SCENE-3 in FIG. 1, when displaying the wiring pattern 110, the information processing apparatus 100 displays the wiring pattern 110 in a state in which the component R1 is located at a distal end of the wiring pattern 110. In this case, since the position of the pin P04 lies at the position of a leading end of the ends of the wiring pattern 110, the position of the pin P01 of the component R1 lies at the position of the distal end of the wiring pattern 110.

Subsequently, the information processing apparatus 100 determines whether or not the area of the first wiring pattern overlaps the areas of the already placed components and the areas of the already wired wiring patterns. The “areas” are also referred to as, for example, “occupied areas”. Each occupied area includes at least the outer shape of the corresponding component and the terminals of the component. The designer may designate the occupied area so that it includes at least the outer shape of the corresponding component and the terminals of the component. For example, the occupied area is an area including the largest outer shape of the corresponding component and the terminals of the component. Also, for example, the occupied area is an area including the largest outer shape with a margin width. The margin width is a numerical value that the designer may set depending on design conditions, manufacturing conditions, test conditions, and so on. Checking whether or not the areas overlap each other is also referred to as “interference check”.

Upon receiving an instruction for finalizing the placement of the first component, as illustrated in SCENE-4 in FIG. 1, the information processing apparatus 100 determines whether or not the area of the first component overlaps the areas of the already placed components and the areas of the already wired wiring patterns when the first component is placed at the position of the distal end of the route.

Upon determining that the area of the first wiring pattern and the area of the first component do not overlap the areas of the already placed components and the areas of the already wired wiring patterns, the information processing apparatus 100 finalizes the placement of the first component at the position of the distal end and also finalizes the first wiring pattern. Finalizing the first wiring pattern means finalizing a wiring pattern so that it runs along the received route. Also, in the processing for finalizing the placement of the first component and the first wiring pattern, the information processing apparatus 100 registers the placement of the first component and the route for the first wiring pattern in information regarding the design of the printed circuit board 102.

As illustrated in SCENE-5 in FIG. 1, the information processing apparatus 100 finalizes the placement of the component R1 at the position of the distal end of the wiring pattern 110 and also finalizes the wiring pattern 110. In this case, finalizing the placement of the component R1 and the wiring pattern 110 means, for example, registering information regarding the placement of the component R1 and information regarding the wiring pattern 110 in design information or the like regarding the design of the printed circuit board 102. This makes it possible to perform placement work while performing wiring work, thus making it possible to reduce redoing of the placement work and the wiring work.

FIG. 2 is a diagram illustrating an example of component movement and wiring owing to congestion of wiring channels. In related techniques, there are cases in which, even for already placed components, placement work is performed again on a sub-component, owing to congestion of wiring channels or the like. In these cases, wiring work may be performed after the placement work is performed again.

As illustrated at the left side in FIG. 2, three components, that is, a large component 201, a component 202, a two-terminal component 203, are already placed. The designer may expect that, for example, a pin of the two-terminal component 203 is connected to a pin of the component 201 with a wiring pattern 211, as illustrated at the left side in FIG. 2.

However, in practice, since wiring for the components 201 and 202, other than the two-terminal component 203, is performed earlier, as illustrated at the center in FIG. 2, it is difficult to provide connection between terminals, like that for the wiring pattern 211, owing to a wiring channel shortage due to wires in the vicinity of the component 203. Accordingly, as illustrated at the right side in FIG. 2, the two-terminal component 203 is moved, and then wiring work for providing connection between the pin of the component 203 and the pin of the component 201 is performed.

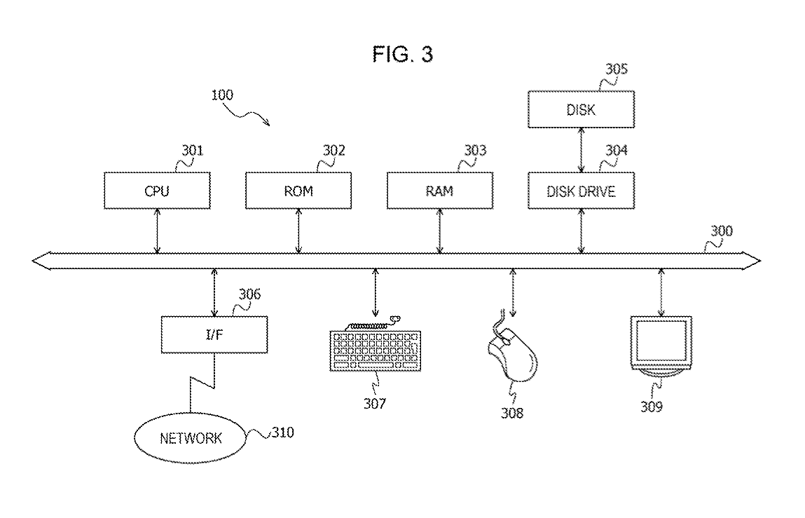

FIG. 3 is a diagram illustrating an exemplary hardware configuration of an information processing apparatus. The information processing apparatus 100 includes a central processing unit (CPU) 301, a read-only memory (ROM) 302, a random access memory (RAM) 303, and a disk drive 304. The information processing apparatus 100 further includes an interface (I/F) 306, a keyboard 307, a mouse 308, and a display 309. The CPU 301, the ROM 302, the RAM 303, the disk drive 304, the I/F 306, the keyboard 307, the mouse 308, and the display 309 are coupled to each other through a bus 300.

The CPU 301 is responsible for overall control of the information processing apparatus 100. The ROM 302 stores therein a program, such as a boot program. The RAM 303 is used as a work area for the CPU 301. In accordance with control performed by the CPU 301, the disk drive 304 controls writing/reading of data to/from a disk 305. The disk 305 stores therein data written under the control of the disk drive 304. Examples of the disk 305 include a magnetic disk and an optical disk.

The I/F 306 is coupled to a network 310, which includes a local area network (LAN), a wide area network (WAN), the Internet, or the like, through a communication link and is further coupled to another apparatus through the network 310. The I/F 306 is responsible for interfacing between the network 310 and the internal elements and controls input/output of data from an external device. The I/F 306 may be implemented by, for example, a modem or a LAN adapter.

The keyboard 307 and the mouse 308 are interfaces for receiving inputs of various types of data via operations of a user. The display 309 is an interface for outputting data in accordance with an instruction from the CPU 301.

Although not illustrated, the information processing apparatus 100 may include a solid state drive (SSD), a semiconductor memory, or the like. Also, although not illustrated, the information processing apparatus 100 may be provided with an input device, such as a camera for capturing still images or moving images or a microphone for picking up sound. In addition, although not illustrated, the information processing apparatus 100 may be provided with an output device, such as a printer.

Although a case in which the information processing apparatus 100 is a personal computer is described in the present embodiment as an exemplary hardware configuration of the information processing apparatus 100, the present disclosure is not limited thereto, and the information processing apparatus 100 may be a server or the like. When the information processing apparatus 100 is a server, the information processing apparatus 100 may be coupled to an apparatus operable by the user, the display 309, and so on through the network 310.

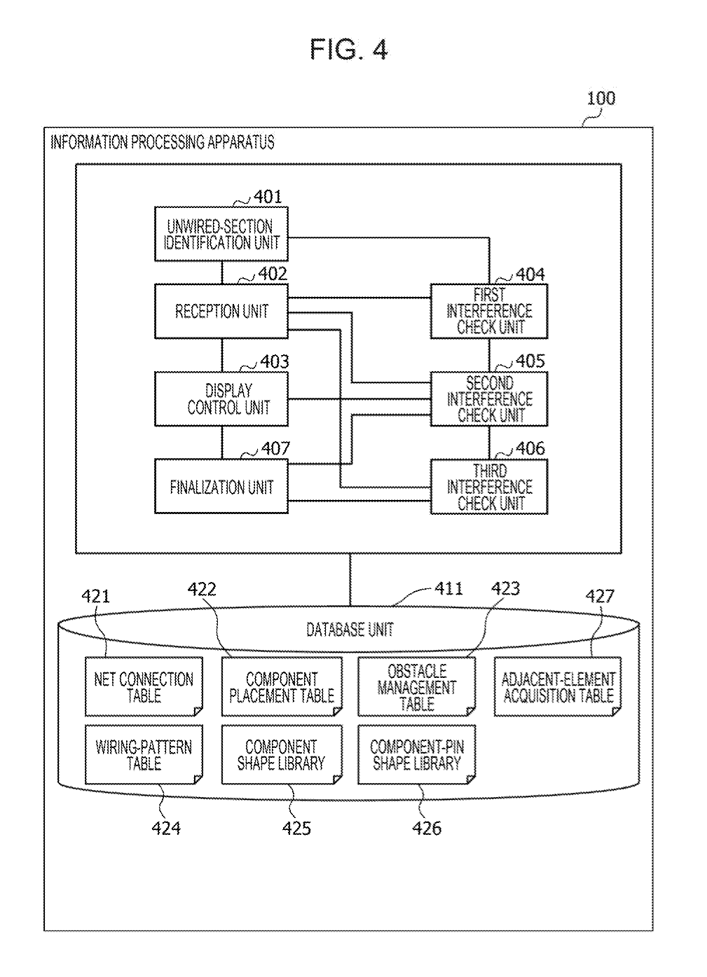

FIG. 4 is a diagram illustrating an exemplary functional configuration of the information processing apparatus 100. The information processing apparatus 100 includes an unwired-section identification unit 401, a reception unit 402, a display control unit 403, a first interference check unit 404, a second interference check unit 405, a third interference check unit 406, a finalization unit 407, and a database unit 411. Processing performed by a control unit constituted by the reception unit 402, the display control unit 403, the first interference check unit 404, the second interference check unit 405, the third interference check unit 406, and the finalization unit 407 is coded, for example, into a program stored in a storage medium, such as the ROM 302, the RAM 303, or the disk 305, that is accessible by the CPU 301 illustrated in FIG. 3. The CPU 301 reads the program from the storage medium and executes the processing coded into the program. This realizes the processing performed by the control unit. A processing result of the control unit is stored, for example, in the storage medium, such as the RAM 303, the ROM 302, or the disk 305.

The display control unit 403 also controls the display 309 and so on to display, on the screen thereof, a printed circuit board and components in a simulation space.

The database unit 411 is implemented by, for example, the RAM 303, the ROM 302, or the disk 305. The database unit 411 stores therein a net connection table 421, a wiring-pattern table 424, a component placement table 422, an obstacle management table 423, a component shape library 425, a component-pin shape library 426, an adjacent-element acquisition table 427, and so on.

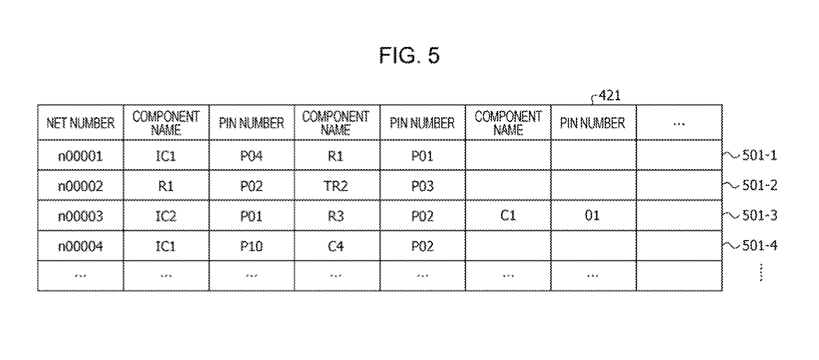

FIG. 5 is a diagram illustrating an exemplary data structure of the net connection table 421. The net connection table 421 includes records for respective nets. Each record indicates between which components each net provides connection. Each record of the net connection table 421 includes a “net number” field, “component name” fields, and “pin number” fields. Upon entry of information in the fields, records (records 501-1 to 501-4 and so on) are stored in the net connection table 421. A net number is entered in the “net number” field as the identification information of the net. A component name is entered in the “component name” field as the identification information of a component connected to the net. A pin number is entered in the “pin number” field as the identification information of a pin of the component connected to the net. The number of the “component name” fields and the “pin number” fields differ depending on components to be connected to the net and the number of pins.

For example, in the case of the record 501-1, a net n00001 provides connection between the pin P04 of the component IC1 and the pin P01 of the component R1.

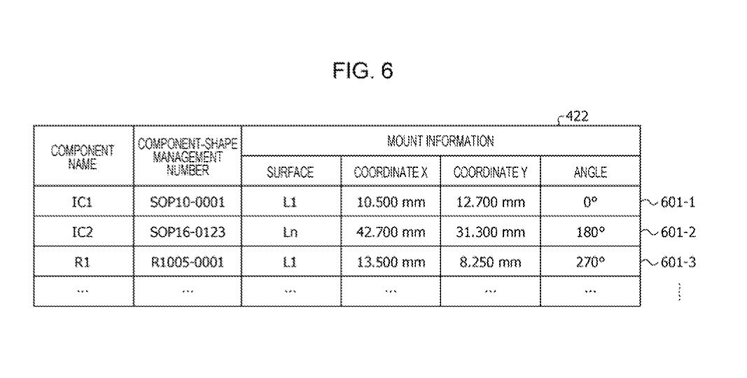

FIG. 6 is a diagram illustrating an exemplary data structure of the component placement table 422. The component placement table 422 includes records indicating placement of components on a printed circuit board. Each record of the component placement table 422 includes, for example, a “component name” field, a “component-shape management number” field, and a “mount information” field. Upon entry of information in the fields, records (records 601-1 to 601-3 and so on) are stored in the component placement table 422.

A component name is entered in the “component name” field as the identification information of a component. A component-shape management number is entered in the “component-shape management number” field as the identification information of a component shape of the component. The “mount information” field includes a “surface” field, a “coordinate X” field, a “coordinate Y” field, and an “angle” field. The identification information of a surface of a printed circuit board is entered in the “surface” field. The component is provided on that surface. An X coordinate value is entered in the “coordinate X” field as position information of the component on the printed circuit board. A Y coordinate value is entered in the “coordinate Y” field as position information of the component on the printed circuit board. Information indicating in which orientation the component is placed at the position on the printed circuit board is entered in the “angle” field. The position is represented by the X coordinate value and the Y coordinate value. The information indicating in which orientation the component is placed is, for example, a rotation angle of the component.

For example, in the case of the record 601-1, the shape of the component IC1 is a shape indicated by a component-shape management number SOP10-0001, and the component IC1 is placed on a surface L1 at the position indicated by coordinates (10.500, 12.700) at an angle of 0°. Since details of individual shapes are defined in the component shape library 425 (described later), the occupied area of each component may be identified using the component-shape management number.

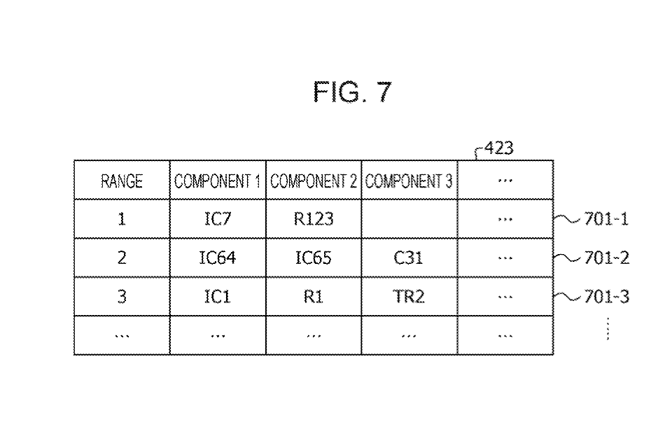

FIG. 7 is a diagram illustrating an exemplary data structure of the obstacle management table 423. The obstacle management table 423 includes records regarding already placed components and already wired pattern elements. Each record of the obstacle management table 423 includes a “range” field and “component” fields. Upon entry of information in the fields, records (records 701-1 to 701-3 and so on) are stored in the obstacle management table 423.

The identification information of a range within a predetermined distance from a reference point is entered in the “range” field for each reference point. Examples of the reference point include the start point of a wiring pattern, the end point of a wiring pattern, and a turn-back point. The component name of a component included in the range is entered in the “component” field.

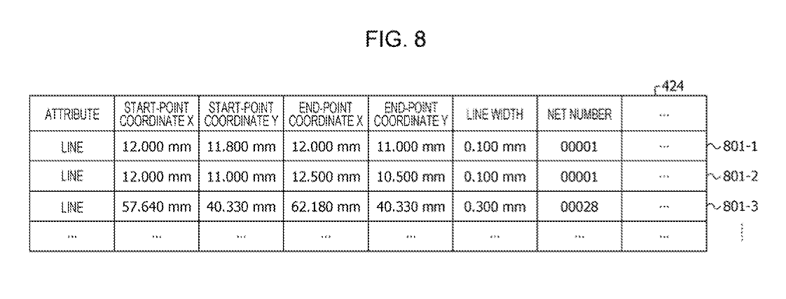

FIG. 8 is a diagram illustrating an exemplary data structure of the wiring-pattern table 424. The wiring-pattern table 424 includes records indicating finalized wiring patterns. Each record of the wiring-pattern table 424 includes an “attribute” field, a “start-point coordinate X” field, a “start-point coordinate Y” field, an “end-point coordinate X” field, an “end-point coordinate Y” field, a “line width” field, and a “net number” fields Upon entry of information in the fields, records (records 801-1 to 801-3, and so on) are stored in the wiring-pattern table 424.

An attribute of a wiring pattern is entered in the “attribute” field. Examples of the attribute of a wiring pattern include “line”, “via”, “land”, and “solid”. The X coordinate value of the start point of a wiring pattern is entered in the “start-point coordinate X” field as start-point information of the wiring pattern. The Y coordinate value of the start point of the wiring pattern is entered in the “start-point coordinate Y” field as start-point information of the wiring pattern. The X coordinate value of the end point of the wiring pattern is entered in the “end-point coordinate X” field as end-point information of the wiring pattern. The Y coordinate value of the end point of the wiring pattern is entered in the “end-point coordinate Y” field as end-point information of the wiring pattern. The width of the wiring pattern is entered in the “line width” field. The net number of a net expressed by the wiring pattern is entered in the “net number” field.

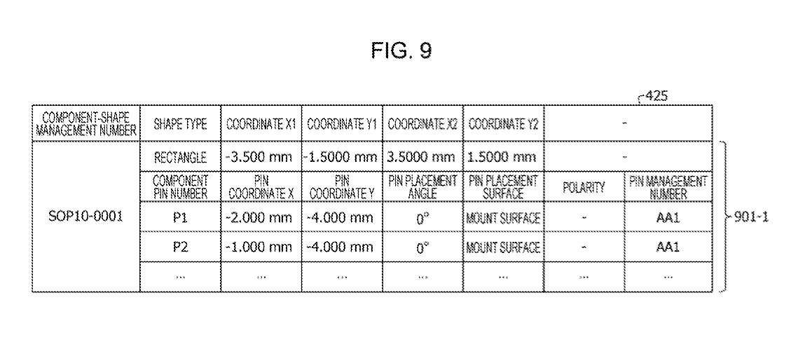

FIG. 9 is a diagram illustrating an exemplary data structure of the component shape library 425. The component shape library 425 includes records indicating the occupied areas of components, the shapes of the components, and the shapes of component pins. Each record of the component shape library 425 includes a “component-shape management number” field, a “shape type” field, “coordinate X” fields, and “coordinate Y” fields. Each record of the component shape library 425 further includes “component pin number” fields, “pin coordinate X” fields, “pin coordinate Y” fields, “pin placement angle” fields, “pin placement surface” fields, “polarity” fields, and “pin management number” fields. Upon entry of information, records (record 901-1 and so on) are stored in the component shape library 425.

A management number of a component shape is entered in the “component-shape management number” field as the identification information of a component shape. The type of shape of a component is entered in the “shape type” field.

The X coordinate values of vertices of a rectangle in a local coordinate system of the component are entered in the “coordinate X” fields. The Y coordinate values of vertices of the rectangle in the local coordinate system of the component are entered in the “coordinate Y” fields. A coordinate system defined on the printed circuit board is a global coordinate system. In this case, the origin in the local coordinate system of the component is associated with coordinates listed in the component placement table 422. For example, when the shape of the component is a rectangle, coordinate values of two diagonal vertices among the vertices of the rectangle are entered in the component shape library 425.

A component pin number is entered in the “component pin number” field as the identification information of a pin of the component. An X coordinate value of the pin of the component is entered in the “pin coordinate X” field as position information of the pin of the component. A Y coordinate value of the pin of the component is entered in the “pin coordinate Y” field as position information of the pin of the component.

The orientation of the pin relative to the component is entered in the “pin placement angle” field. For example, when the orientation of 0° defined for the component and the orientation of the pin are the same, 0° is entered in the “pin placement angle” field.

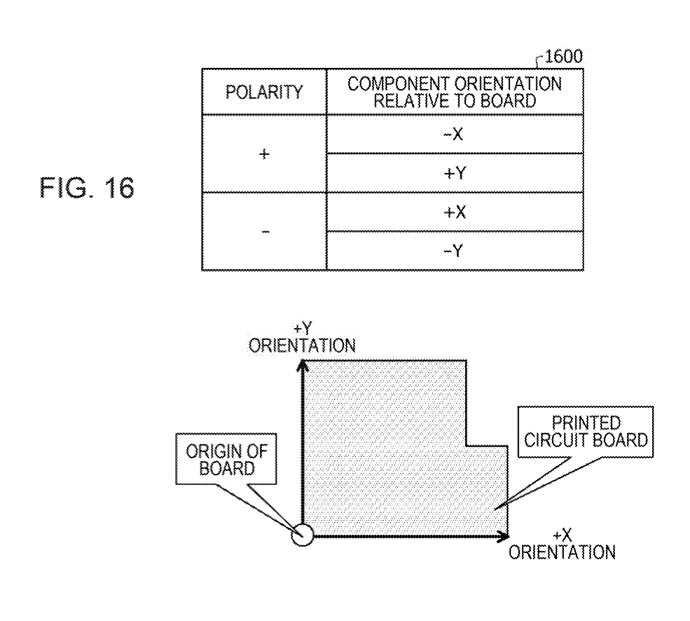

When a polarity is defined for the component, information indicating the polarity is entered in the “polarity” field. For example, when the component is a capacitor, “+” or “−” is entered in the “polarity” field. For example, when the component is a diode, “anode” or “cathode” is entered in the “polarity” field. In FIG. 16, which is referenced later, an example is illustrated in which the placement orientation of a component is restricted by a polarity defined for a pin of the component in an example of the case in which the polarity is “+” or “−”.

Information indicating a surface of the component, on which the pin is placed, is entered in the “pin placement surface” field. When the pin is placed on a surface on which a component is to be placed, for example, “mount surface” is entered in the “pin placement surface” field.

A pin management number for associating the pin of the component with the component-pin shape library 426 is entered in the “pin management number” field.

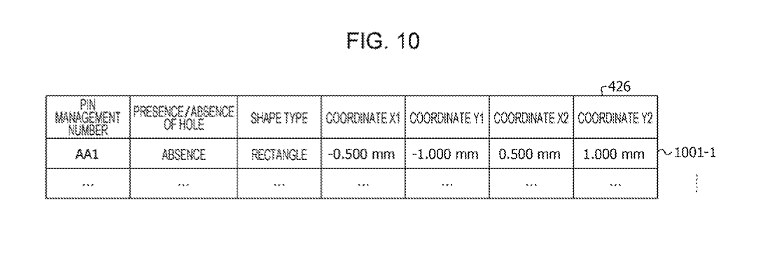

FIG. 10 is a diagram illustrating an exemplary data structure of the component-pin shape library 426. The component-pin shape library 426 includes records indicating the shapes of component pins. Each record of the component-pin shape library 426 includes, for example, a “pin management number” field, a “presence/absence of hole” field, a “shape type” field, “coordinate X” fields, and “coordinate Y” fields. Upon entry of information in the fields, records (record 1001-1 and so on) are stored in the component-pin shape library 426.

A pin management number indicating the type of pin is entered in the “pin management number” field. Information indicating whether or not a pin of a component is to be inserted into a hole in a printed circuit board is entered in the “presence/absence of hole” field. For example, when the pin of the component is to be inserted into a hole in a printed circuit board, “presence” is entered in the “presence/absence of hole” field, and when the pin of the component is not to be inserted into a hole in a printed circuit board, “absence” is entered in the “presence/absence of hole” field.

Information indicating the shape of a pin is entered in the “shape type” field. For example, when the shape of the pin is quadrangular, “rectangle” is entered in the “shape type” field. The X coordinate values of vertices of a rectangle in a local coordinate system of the pin are entered in the “coordinate X” fields. The Y coordinate values of vertices of the rectangle in the local coordinate system of the pin are entered in the “coordinate Y” fields.

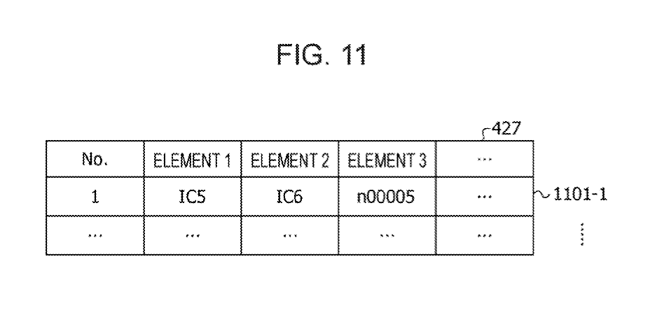

FIG. 11 is a diagram illustrating an exemplary data structure of the adjacent-element acquisition table 427. The adjacent-element acquisition table 427 includes records indicating adjacent elements obtained from the obstacle management table 423. The adjacent elements are elements that exist within a predetermined distance from a designated position. Examples of the elements include wired wiring patterns, such as “line”, “via”, “land”, and “solid”, and already placed components.

Each record of the adjacent-element acquisition table 427 includes a “number” field and “element” fields for obtained elements. Upon entry of information in the fields, records (record 1101-1 and so on) are stored in the adjacent-element acquisition table 427. The number for identifying a designated position is entered in the “number field”. The element names of respective elements located within a predetermined distance from the designated position are entered in the “element” fields.

Referring back to FIG. 4, the display control unit 403 displays the first component in a state in which the first terminal is located on the second terminal of the second component. The second terminal of the second component has a connection relationship with the first terminal of the first component.

An unwired section may be pre-identified to determine between which components wiring work for a wiring pattern is to be performed. Based on the wiring-pattern table 424 and the net connection table 421, the unwired-section identification unit 401 identifies the unwired section. The unwired-section identification unit 401 identifies, as an unwired section, a net that is included in nets registered in the net connection table 421 and that is not registered in the wiring-pattern table 424. With respect to a pin of a component which is to be connected to a net that is an unwired section, the display control unit 403 may also display information indicating that the pin is not yet wired. The display control unit 403 displays, for example, a pin of a component to be connected to a net that is an unwired section, by using a color different from pins of components that are already wired.

When an unwired section is identified, the reception unit 402 receives a pin of a component, which is selected by the user's operation.

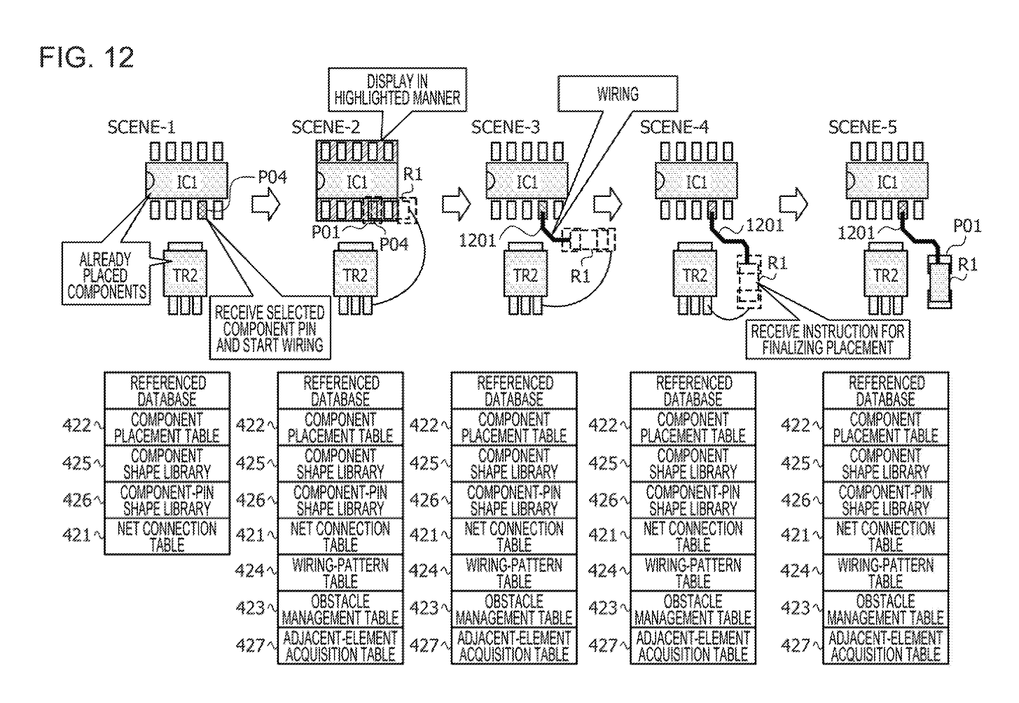

FIG. 12 is a diagram illustrating a first wiring example. As illustrated in FIG. 12, the display control unit 403 displays components that are already placed on a printed circuit board in a simulation space, based on the component placement table 422, the component shape library 425, the component-pin shape library 426, and the net connection table 421.

In the example in SCENE-1 in FIG. 12, the already placed second component is a component IC1. As illustrated in SCENE-1 in FIG. 12, the second terminal is a pin P04 of the component IC1. Wiring work is started with the pin P04 of the component IC1 as a start point for the wiring work.

The display control unit 403 displays the unplaced first component in a state in which the first terminal of the first component is located on the second terminal of the second component. The second terminal of the second component has a connection relationship with the first terminal. Here, the first component is, for example, a two-terminal component. Based on the net connection table 421, the display control unit 403 may identify the first terminal at the end point of the net connected to the second terminal of the second component and the first component having the first terminal at the end point.

According to the net connection table 421, the pin P01 at the end point of the net n00001 to be connected to the pin P04 of the component IC1 is included in the component R1. At this time, the display control unit 403 displays the components already placed on the printed circuit board and an unplaced two-terminal component such that they are distinguishable from each other. Therefore, as illustrated in SCENE-2 in FIG. 12, the first component is the component R1, and the first terminal is the pin P01.

The display control unit 403 varies the display color, the display line width, the line type, and so on between the components already placed on the printed circuit board and the two-terminal component. This makes it possible to distinguish between the components already placed on the printed circuit board and the unplaced two-terminal component.

The first interference check unit 404 also determines whether or not the occupied area of the component IC1 having the selected pin P04 and the occupied area of the unplaced two-terminal component R1 overlap each other. The “overlap of the areas” is also referred to as “interference”. Determining whether or not the areas overlap each other is also referred to as “interference check”. When there is interference, the first interference check unit 404 determines that there is an error.

As described above, the occupied area is an area including at least the outer shape of a component and pins of the component. The occupied area of a component may be, for example, an area including the largest outer shape of a component and pins of the component. The occupied area of each component may be an area having a margin of a predetermined length in each direction from the area including the largest outer shape.

As illustrated in SCENE-2 in FIG. 12, when the first interference check unit 404 determines that the occupied area of the component IC1 and the occupied area of the unplaced two-terminal component R1 overlap each other, the display control unit 403 displays the occupied area of the component IC1 in a highlighted manner in order to indicate that the areas overlap each other.

The display control unit 403 displays a first wiring pattern that connects from the second terminal to the first terminal, along a route designated from the second terminal. As illustrated in SCENE-3 in FIG. 12, the first wiring pattern is a wiring pattern 1201. As illustrated in SCENE-3 in FIG. 12, the reception unit 402 receives a designated route of the wiring pattern 1201 that connects from the component IC1 to the component R1. In this case, it is assumed that the route is designated by operating the mouse 308. The reception unit 402 obtains position information of a mouse pointer during the operation of the mouse 308.

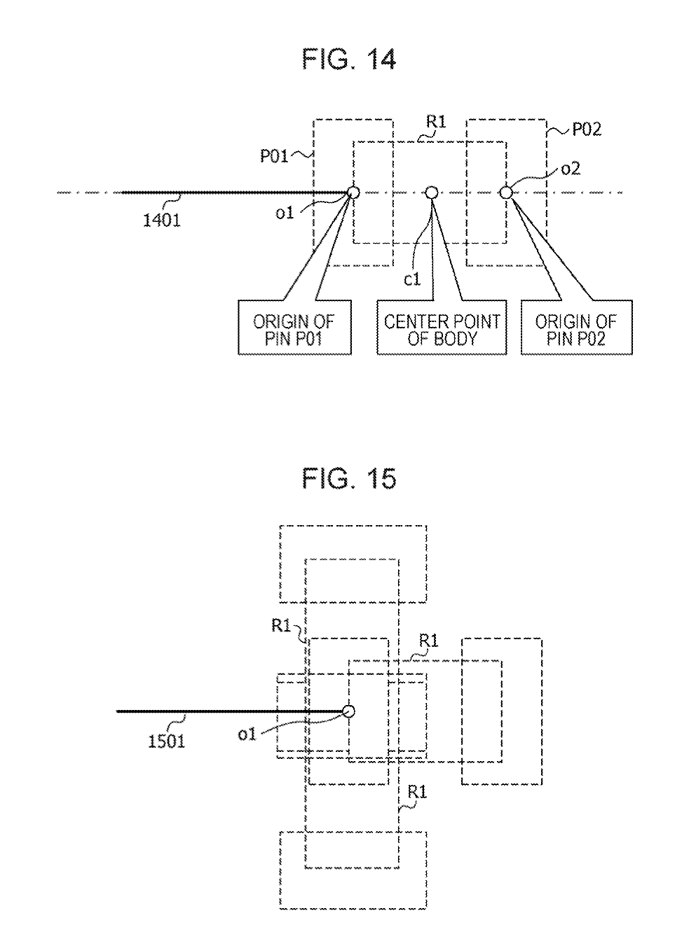

The display control unit 403 then displays the wiring pattern 1201 so that it runs along the received route and also displays the component R1 at the distal end of the wiring pattern 1201, based on the component shape library 425 and the component-pin shape library 426. Detailed examples of a case in which the component R1 is displayed at the distal end of the wiring pattern 1201 will be described later with reference to FIGS. 14 to 17.

Next, the second interference check unit 405 checks interference between the first wiring pattern and the already placed components or the already wired wiring patterns, with respect to the occupied areas. Although it is not illustrated, when it is determined that the wiring pattern 1201 to be provided along the received route and a component or a wiring pattern already placed on the printed circuit board interfere with each other, the display control unit 403 outputs information indicating that the wiring pattern 1201 is not to be provided along the designated route. The display control unit 403 does not display, for example, the wiring pattern on the designated route.

Upon receiving an instruction for finalizing the route, the third interference check unit 406 determines whether or not the area of the first component overlaps the areas of the already placed components or the areas of the already wired wiring patterns when the first component is placed at the position of the distal end of the route. As illustrated in SCENE-4 in FIG. 12, the reception unit 402 receives an instruction for finalizing the placement of the component R1. Upon receiving the instruction for the placement finalization, the third interference check unit 406 obtains, from the obstacle management table 423, elements adjacent to the component R1 when the component R1 is provided at the position of the distal end of the designated route at the time of receiving the instruction. The third interference check unit 406 then stores, in the adjacent-element acquisition table 427, information indicating the position of the distal end of the route and the obtained adjacent elements.

The third interference check unit 406 checks interference between the component R1 and the respective obtained adjacent elements. The interference check in this case determines whether or not the occupied area of the first component and the occupied area of each adjacent element overlap each other.

When it is determined that the area of the first wiring pattern and the area of the first component do not overlap the areas of the already placed components and the areas of the already wired wiring patterns, the finalization unit 407 finalizes the placement of the first component at the position of the distal end and also finalizes the first wiring pattern.

When it is determined that the interference check performed by the third interference check unit 406 and the second interference check unit 405 indicates no error, the finalization unit 407 finalizes the placement of the component R1 at the position of the distal end of the wiring pattern and finalizes the wiring pattern, as illustrated in SCENE-5 in FIG. 12. At this time, the finalization unit 407 stores information indicating the wiring pattern in the wiring-pattern table 424. The finalization unit 407 also stores, in the component placement table 422, information indicating the placement of the component R1.

On the other hand, when it is determined that the area of the first wiring pattern overlaps one of the areas of the already placed components or one of the areas of the already wired wiring patterns, the finalization unit 407 neither finalizes the placement of the first component at the position of the distal end nor finalizes the first wiring pattern. Also, when it is determined that the area of the first component overlaps one of the areas of the already placed components or one of the areas of the already wired wiring patterns, the finalization unit 407 neither finalizes the placement of the first component at the position of the distal end nor finalizes the first wiring pattern. When the placement of the first component and the first wiring pattern are not finalized, the display control unit 403 displays information indicating that the finalization is not permitted.

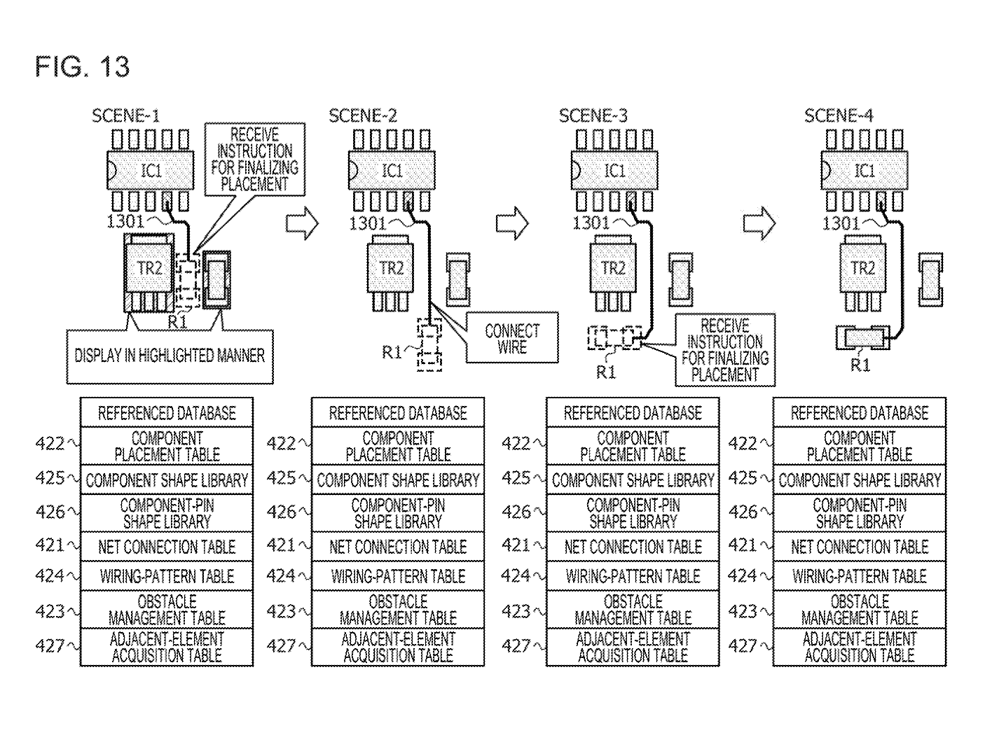

FIG. 13 is a diagram illustrating a second wiring example. In the example illustrated in FIG. 13, the first wiring pattern is a wiring pattern 1301. As illustrated in SCENE-1 in FIG. 13, the reception unit 402 receives an instruction for finalizing the placement of an unplaced component R1. As described above, when the reception unit 402 receives an instruction for finalizing the placement, the third interference check unit 406 obtains, from the obstacle management table 423, elements adjacent to the component R1 when the component R1 is provided at the position of the distal end of a route at the time of receiving the instruction for finalizing the placement. The third interference check unit 406 checks interference between the component R1 and the obtained adjacent elements with respect to the occupied areas. Since the result of the interference check indicates an error, the display control unit 403 displays the adjacent elements that interfere with the component R1 in a highlighted manner, as illustrated in SCENE-1 in FIG. 13. This makes it possible to provide the designer with information indicating that the finalization of the placement of the component R1 and the wiring pattern 1301 is not permitted.

As illustrated in SCENE-2 in FIG. 13, since the finalization unit 407 does not finalize the placement of the component and the wiring pattern, the reception unit 402 receives a designated route for the wiring pattern 1301. The display control unit 403 displays the wiring pattern 1301 along the received route.

As illustrated in SCENE-3 in FIG. 13, the reception unit 402 receives an instruction for finalizing the placement of the component R1. After receiving the instruction for finalizing the placement, the third interference check unit 406 obtains, from the obstacle management table 423, elements adjacent to the component R1 when the component R1 is provided at the position of the distal end of the route at the time of receiving the instruction for finalizing the placement, as described above. The third interference check unit 406 checks interference between the component R1 and the obtained adjacent elements with respect to the occupied areas.

When it is determined that the interference check performed by the third interference check unit 406 and the second interference check unit 405 indicates no error, the finalization unit 407 finalizes the placement of the component R1 at the position of the distal end of the wiring pattern and also finalizes the wiring pattern 1301, as illustrated in SCENE-4 in FIG. 13.

Next, display orientations and placement orientations of an unplaced component during wiring work will be described with reference to FIGS. 14 to 17.

FIG. 14 is a diagram illustrating an exemplary display of an unplaced component. In this example, the first wiring pattern is a wiring pattern 1401. As described above, the first terminal is a pin P01 of a component R1. Another terminal of the first component which is different from the first terminal is a pin P02 of the component R1.

The display control unit 403 displays the component R1 in a state in which the pin P01, which is the first terminal, of the component R1 is located at a distal end of the wiring pattern 1401, and the pins P01 and P02 of the component R1 are located on an extended straight line of the wiring pattern 1401. The component R1 is oriented such that the wiring pattern 1401 and the pin P02 do not overlap each other.

As illustrated in FIG. 14, an origin o1 of the pin P01 is located at the distal end of the wiring pattern 1401, and a center point c1 of the body of the component R1 and an origin o2 of the pin P02 are located on the extended straight line of the wiring pattern 1401. The orientation of the component R1 illustrated in FIG. 14 is also referred to as an “orientation of 0°” or a “default orientation”.

When an instruction for finalizing the component placement is received, the third interference check unit 406 checks interference between the component R1, which is placed in the default orientation at the distal end of the wiring pattern, and an already placed element. When finalizing the component placement, the finalization unit 407 finalizes the placement of the component R1 in the default orientation at the distal end of the wiring pattern.

FIG. 15 is a diagram illustrating an exemplary display of an unplaced component in a plurality of orientations. The display control unit 403 displays the first component in a plurality of orientations in a state in which the first terminal is located at the position of a distal end of a wiring pattern. The plurality of orientations are mountable orientations among pre-set orientations. In the example illustrated in FIG. 15, the plurality of orientations are three orientations, that is, the default orientation illustrated in FIG. 14, an orientation of +90° from the default orientation, and an orientation of −90° from the default orientation. In an orientation of +180° from the default orientation, the pin P02 is placed on a wiring pattern 1501, and thus mounting of the first component is not permitted.

When receiving an instruction for finalizing the placement of an unplaced component, the reception unit 402 also receives an instruction indicating in which of the orientations the placement of the component is to be finalized. The third interference check unit 406 then checks interference between the component, which is placed in the orientation indicated by the instruction, and adjacent elements.

The plurality of orientations are orientations based on a polarity defined for terminals of the component. The polarity is defined in the component shape library 425. As described above, when the component of interest is a diode, a capacitor, or the like, the polarity is defined.

FIG. 16 is a diagram illustrating an exemplary definition of orientations based on a polarity. Placement restriction information 1600 defines the component orientations relative to a printed circuit board for respective polarities. The placement restriction information 1600 is determined based on Design for Manufacturing (DFM) or Design for Test (DFT). The placement restriction information 1600 is stored, for example, in a storage medium, such as the ROM 302, the RAM 303, or the disk 305.

According to the placement restriction information 1600, for example, the orientation of a component is “−X orientation” or “+Y orientation” when the polarity is “+”. In contrast, according to the placement restriction information 1600, for example, the orientation of a component is “+X orientation” or “−Y orientation”, when the polarity is “−”.

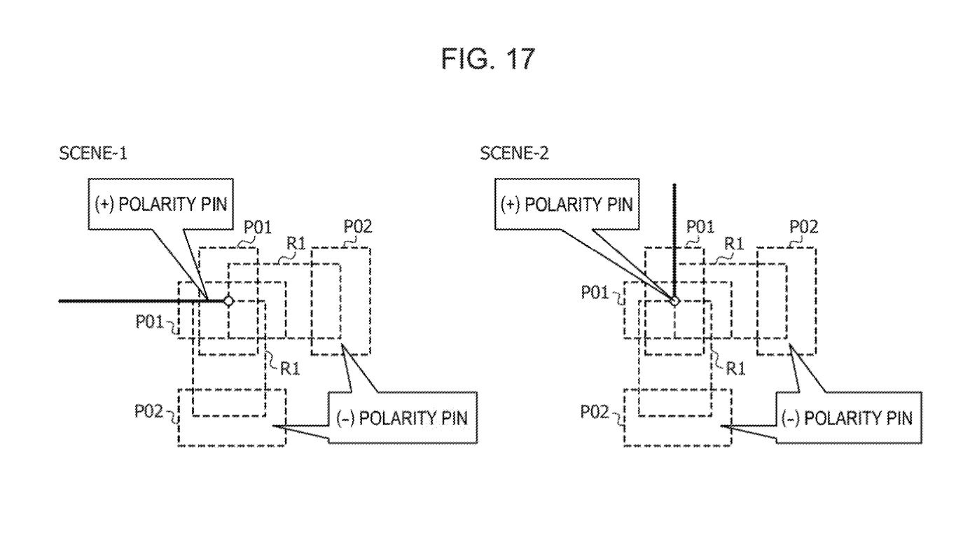

FIG. 17 is a diagram illustrating an exemplary display of an unplaced component in orientations based on a polarity thereof. In the examples in SCENE-1 and SCENE-2 in FIG. 17, when the polarity of the pin P01 is “+”, the pin P01 is provided in “−X orientation” relative to the pin P02, or the pin P01 is provided in “+Y orientation” relative to the pin P02, based on the placement restriction information 1600.

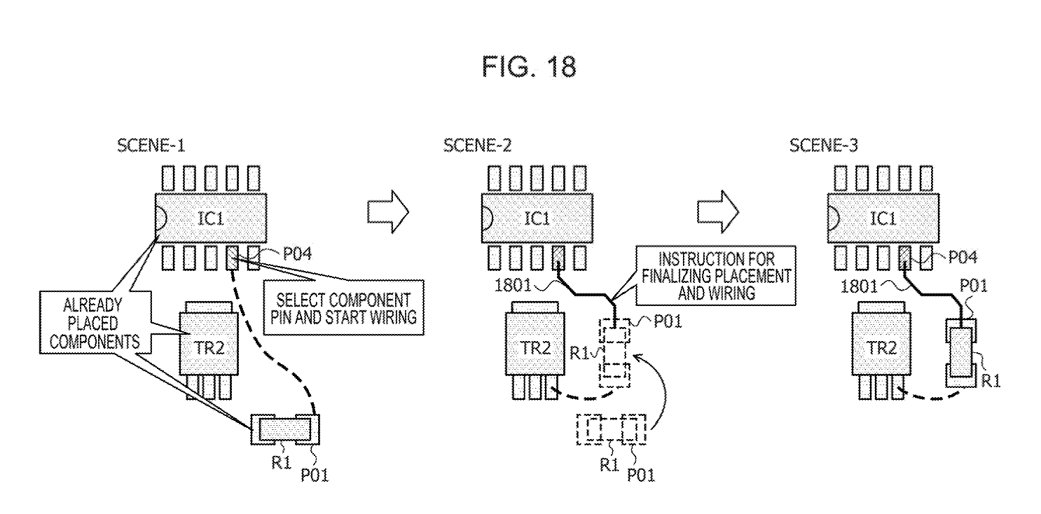

FIG. 18 is a diagram illustrating an example of a wiring pattern between already placed components. As illustrated in SCENE-1 in FIG. 18, there is a case in which a component R1 including a pin p01 having a connection relationship with a selected pin P04 of an already placed component IC1 is already placed. In such a case, the display control unit 403 does not display a component to be connected in a state in which a pin thereof is located on a pin of an already placed component. Instead, the reception unit 402 starts receiving a route for a first wiring pattern from the selected pin P04 of the already placed component IC1, as illustrated in SCENE-1 in FIG. 18. In this case, the first wiring pattern is a wiring pattern 1801. The display control unit 403 then displays the wiring pattern 1801 along the received route. In this case, the component R1 to be connected is already placed, and thus, when displaying the wiring pattern 1801, the display control unit 403 does not display the component R1 at the distal end of the wiring pattern 1801. As described above, the second interference check unit 405 checks interference between the wiring pattern 1801 and the already placed or wired elements.

As illustrated in SCENE-2 in FIG. 18, the reception unit 402 receives an instruction for finalizing the wiring pattern 1801. When the reception unit 402 receives the finalization instruction, the third interference check unit 406 obtains, from the obstacle management table 423, elements adjacent to the component R1 which is provided at the position of the distal end of the route at the time of receiving the finalization instruction. The third interference check unit 406 then stores, in the adjacent-element acquisition table 427, information indicating the position of the distal end of the route and information indicating the obtained adjacent elements. The third interference check unit 406 checks interference between the component R1, which is provided at the position of the distal end of the route, and the adjacent elements.

When it is determined that the result of the interference check performed by the third interference check unit 406 and the second interference check unit 405 indicates no error, the finalization unit 407 moves the component R1 to the position of the distal end of the wiring pattern 1801, finalizes the position of the component R1, and finalizes the wiring pattern 1801, as illustrated in SCENE-3 in FIG. 18.

When a second wiring pattern that connects from a terminal, which is one terminal of the component R1 and different from the first terminal, to a terminal of a third component having a connection relationship with the other terminal is already finalized, the display control unit 403 displays information indicating that the second wiring pattern is already finalized, before the placement of the first component and the first wiring pattern are finalized.

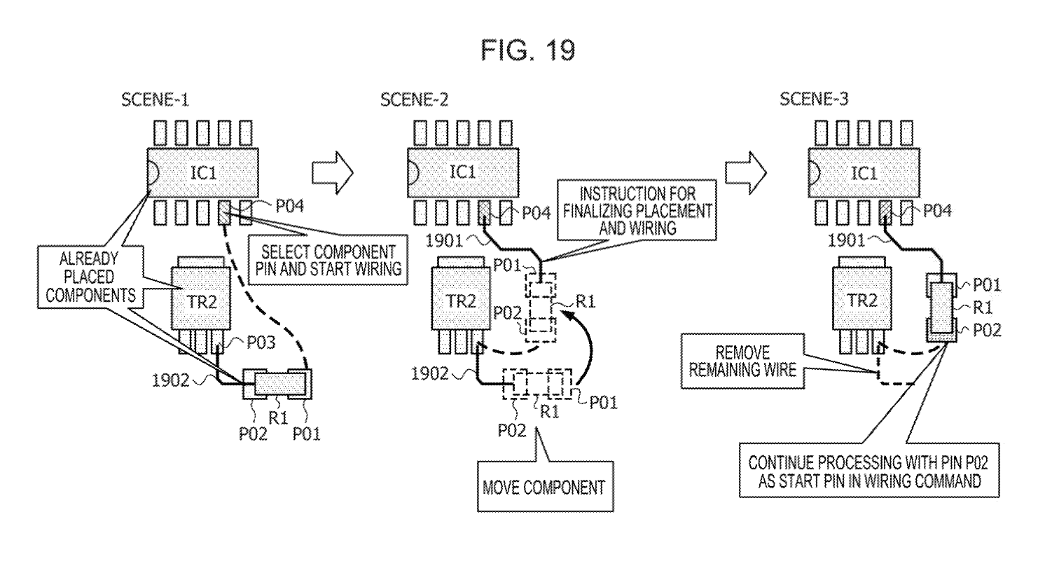

FIG. 19 is a diagram illustrating another example of a wiring pattern between already placed components. The first wiring pattern is a wiring pattern 1901. The second wiring pattern is a wiring pattern 1902. The third component having a connection relationship with a pin P02, which is one terminal of the component R1 and different from the pin P01, is a component TR2. Also, a terminal of the component TR2 which has a connection relationship with the pin P02 of the component R1 is a pin P03.

As illustrated in SCENE-1 in FIG. 19, there is a case in which a component R1 including a pin P01 having a connection relationship with the selected pin P04 of the component IC1 is already placed, and a wiring pattern 1902 that connects from another pin P02 of the component R1 to a pin P03 of another component TR2 is already finalized.

In such a case, the display control unit 403 does not display a component to be connected in a state in which a pin thereof is located on the selected pin of the already placed component. Instead, the reception unit 402 receives a designated route for a wiring pattern from the selected pin P04 of the already placed component IC1, as illustrated in SCENE-1 in FIG. 19. The display control unit 403 then displays the wiring pattern along the received route. Since the component R1 to be connected is already placed, and thus, when displaying the wiring pattern, the display control unit 403 does not display the component R1 at the distal end of the wiring pattern. As described above, the second interference check unit 405 checks interference between the wiring pattern and the already placed elements.

As illustrated in SCENE-2 in FIG. 19, the reception unit 402 receives an instruction for finalizing the wiring pattern. When the reception unit 402 receives the instruction for the finalization, the third interference check unit 406 obtains elements adjacent to the component R1 which is provided at the position of the distal end of the route, as in the above-described example. The third interference check unit 406 then stores, in the adjacent-element acquisition table 427, information indicating the position of the distal end of the route and information indicating the adjacent elements. The third interference check unit 406 checks interference between the component R1, which is provided at the position of the distal end of the route, and the adjacent elements.

When it is determined that the interference check performed by the third interference check unit 406 and the second interference check unit 405 indicates no error, the finalization unit 407 moves the component R1 to the position of the distal end of the wiring pattern 1901, finalizes the placement of the component R1, and finalizes the wiring pattern 1901, as illustrated in SCENE-2 in FIG. 19. At this time, before the finalization unit 407 moves the position of the component R1 and finalizes the placement of the component R1, the reception unit 402 receives information indicating whether or not component movement is to be performed.

When the finalization unit 407 moves the first component R1 to the position of the distal end, finalizes the placement of the first component R1, and finalizes the first wiring pattern, the finalization unit 407 removes the second wiring pattern 1902. Thereafter, the reception unit 402 becomes able to receive a designated route for a third wiring pattern that connects from another terminal to a terminal of a third component TR2.

As illustrated in SCENE-3 in FIG. 19, the finalization unit 407 removes the wiring pattern 1902 wired from the pin P02 of the component R1. Here, “removing the wiring pattern 1902” means, for example, removing information regarding the wiring pattern 1902 from the wiring-pattern table 424. The reception unit 402 becomes able to receive a designated route for a wiring pattern from the pin P02 of the component R1.

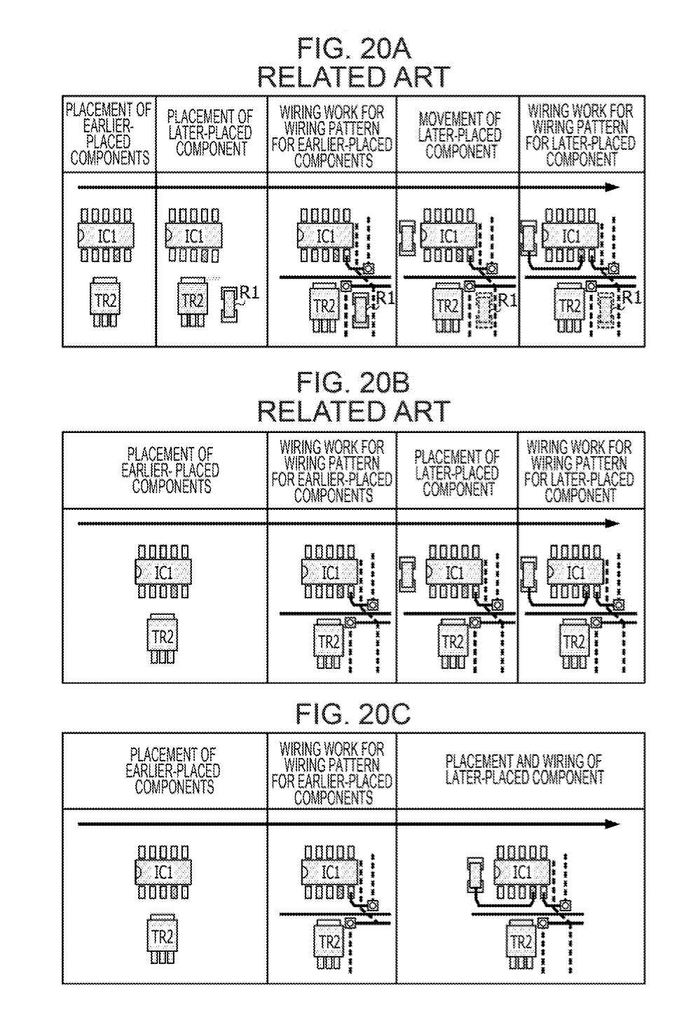

FIGS. 20A and 20B illustrate examples of component placement work and wiring work of related art as comparative examples. FIG. 20C is a diagram illustrating an example of component placement work and wiring work performed by the information processing apparatus 100.

In a related art illustrated in FIG. 20A, components (earlier-placed components) to be placed earlier are first placed. Next, a component (later-placed component) to be placed later is placed. In placement work for the later-placed component, a placement command is executed, and component selection and movement work are performed. In the placement work, the placement of the component is finalized in response to an instruction for finalizing the placement of the component. Next, as illustrated in FIG. 20A, in the related art, wiring work for wiring patterns that provide connections between the earlier-placed components is performed.

Subsequently, as illustrated in FIG. 20A, since wiring work for the later-placed component is not permitted owing to the wiring patterns for the earlier-placed components, work for re-placing the later-placed component is performed. In the work for re-placing the later-placed component, a movement command is executed, and component selection and movement work are performed. Thereafter, in the re-placement work, the placement of the component is finalized in response to an instruction for finalizing the component movement position.

Thereafter, wiring work for the later-placed component is performed. In the wiring work for the later-placed component, a wiring command is executed, and wiring work for the wiring pattern is performed. Then, in the wiring work for the later-placed component, the wiring pattern is finalized in response to an instruction for completing the wiring pattern.

In another related art illustrated in FIG. 20B, earlier-placed components are placed first. Next, wiring work for wiring patterns that provide connections between the earlier-placed components is performed.

Next, a later-placed component is placed, as illustrated in FIG. 20B. In the placement work for the later-placed component, a placement command is executed, and component selection and movement work are performed. In the placement work, the placement of the component is finalized in response to an instruction for finalizing the placement of the component.

Thereafter, wiring work for the later-placed component is performed. In the wiring work for the later-placed component, a wiring command is executed, and wiring work for the wiring pattern is performed. Then, in the wiring work for the later-placed component, the wiring pattern is finalized in response to an instruction for completing the wiring pattern.

As illustrated in FIG. 20C, the information processing apparatus 100 first places earlier-placed components. The information processing apparatus 100 then performs wiring work for wiring patterns that provide connections between the earlier-placed components. Lastly, as illustrated in FIG. 20C, the information processing apparatus 100 performs placement work and wiring work for a later-placed component. In the placement work and wiring work for the later-placed component, by executing a wiring command, the information processing apparatus 100 receives a selected pin of a component at which the wiring is to be started. Next, the information processing apparatus 100 performs pattern wiring work. Thereafter, upon receiving an instruction for finalizing the placement of the component, the information processing apparatus 100 finalizes the component placement and the wiring pattern.

Thus, comparison between FIG. 20A and FIG. 20C indicates that the information processing apparatus 100 reduces rework during the wiring work and the placement work. Also, comparison between FIG. 20B and FIG. 20C indicates that the information processing apparatus 100 may reduce the amount of time taken for the placement work and the wiring work, since the information processing apparatus 100 performs the placement work and the wiring work at the same time.

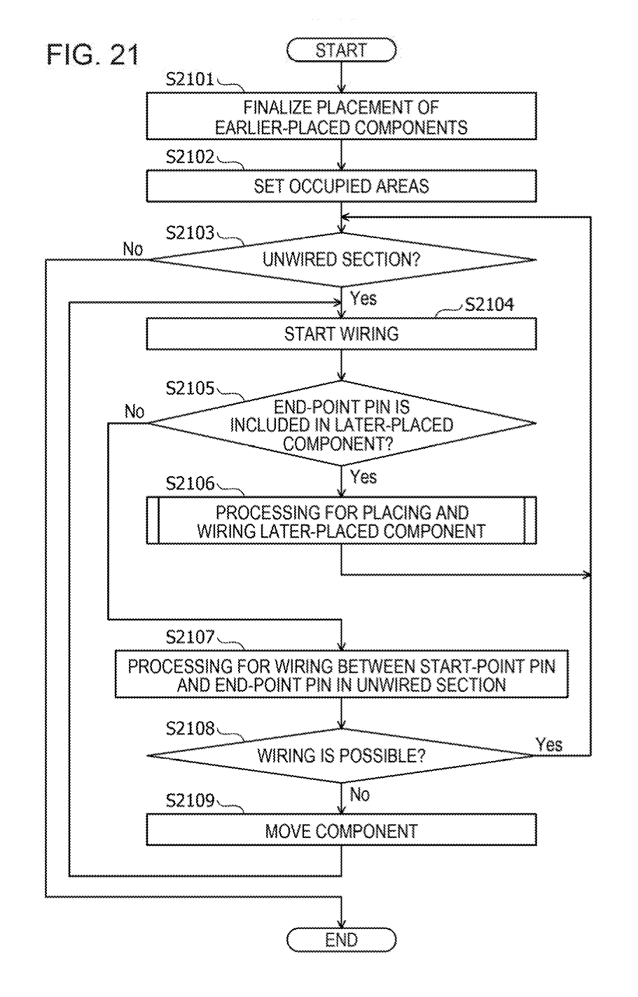

FIG. 21 is a flowchart illustrating an exemplary procedure of component placement processing performed by the information processing apparatus 100. First, the information processing apparatus 100 finalizes the placement of earlier-placed components, such as an LSI and an IC (S2101). Placement information of the earlier-placed components is stored in the component placement table 422. Next, the information processing apparatus 100 sets occupied areas for all the already placed components, based on the component shape library 425 and the component-pin shape library 426 (S2102). The occupied areas set for all the already placed components are stored in the RAM 303, the disk 305, or the like.

Subsequently, the information processing apparatus 100 determines whether or not there is an unwired section (S2103). Upon determining that there is an unwired section (Yes in S2103), the information processing apparatus 100 selects a start-point pin in the unwired section and starts wiring (S2104). The information processing apparatus 100 determines whether or not the end-point pin having a connection relationship with the start-point pin is included in a later-placed component (S2105).

Upon determining that the end-point pin is included in a later-placed component (Yes in S2105), the information processing apparatus 100 performs processing for placing and wiring the later-placed component (S2106) and then returns to S2103. Upon determining that the end-point pin is not included in a later-placed component (No in S2105), the information processing apparatus 100 performs processing for wiring between the start-point pin and the end-point pin in the unwired section (S2107).

Next, the information processing apparatus 100 determines whether or not the wiring is possible (S2108). Upon determining that the wiring is possible (Yes in S2108), the information processing apparatus 100 returns to S2103. Upon determining that the wiring is not possible (No in S2108), the information processing apparatus 100 moves the component including the end-point pin (S2109) and then returns to S2104.

Upon determining that there is no unwired section (No in S2103), the information processing apparatus 100 ends the series of processing.

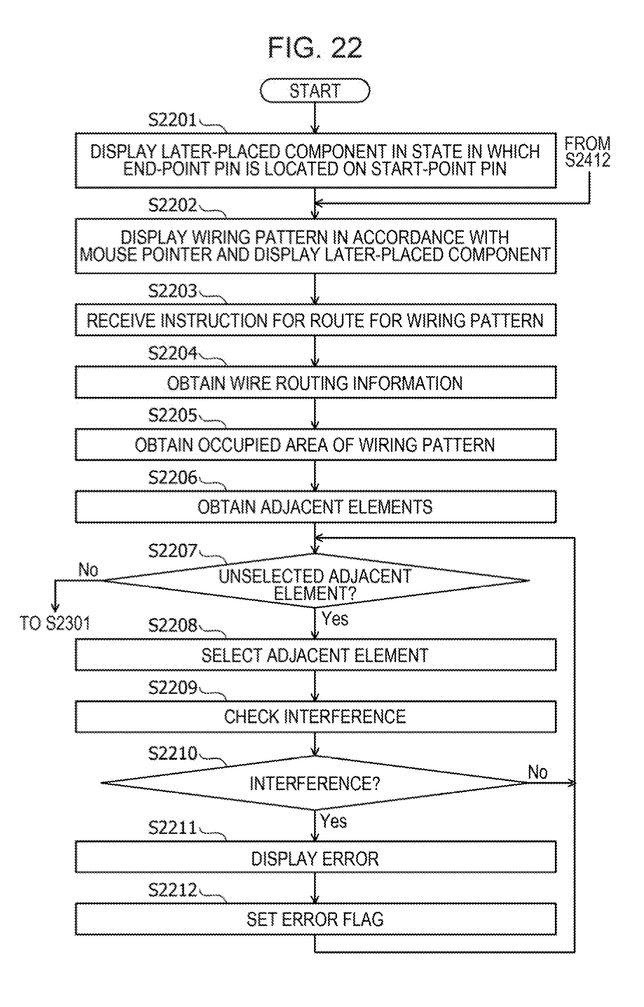

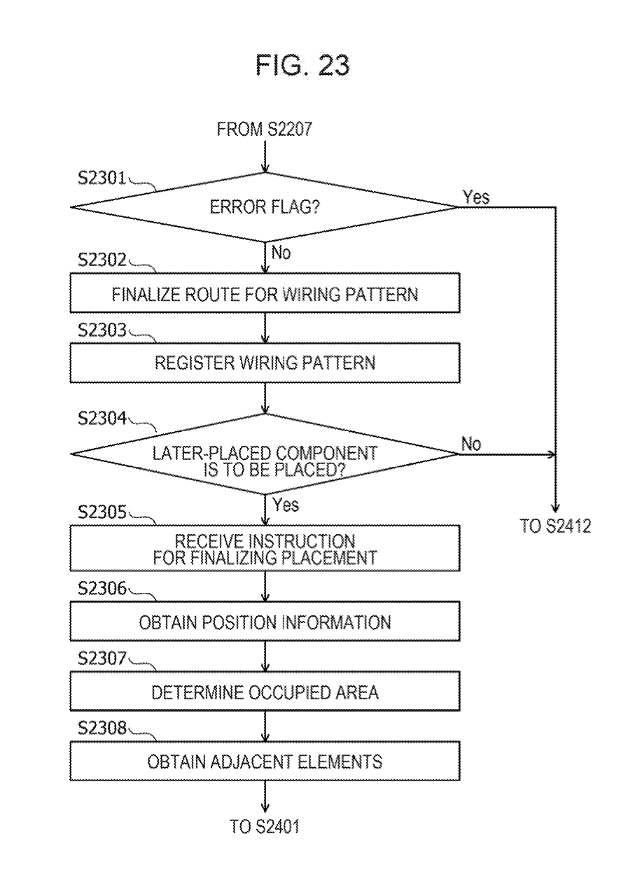

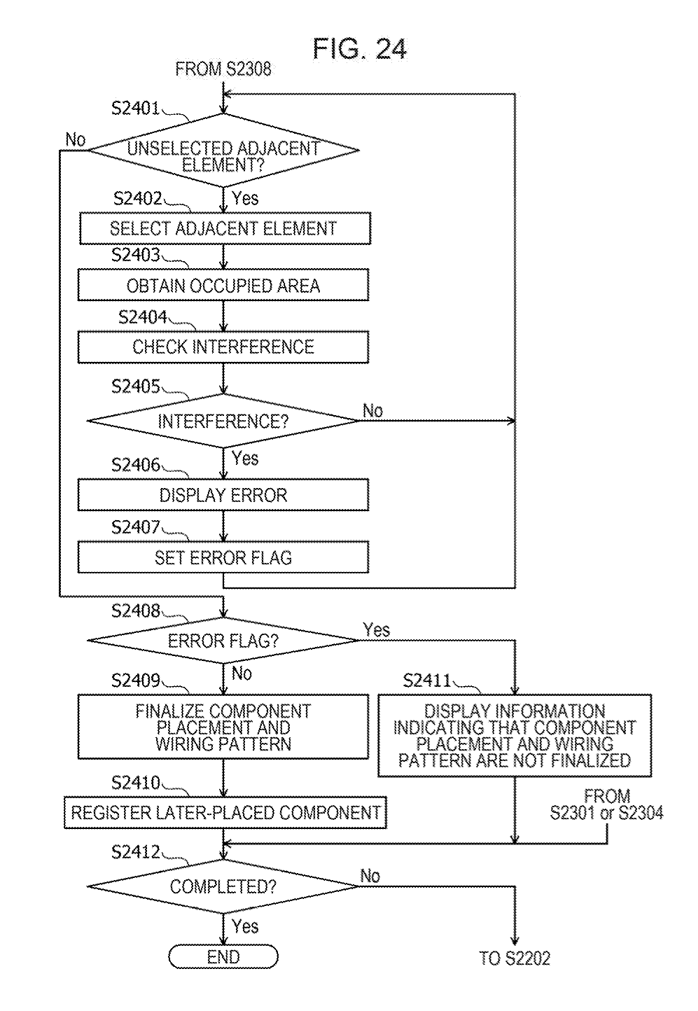

FIGS. 22 to 24 are flowcharts illustrating an exemplary procedure of processing for placing and wiring a later-placed component, which is performed by the information processing apparatus. The information processing apparatus 100 displays a later-placed component in a state in which the end-point pin is located on the start-point pin (S2201). The information processing apparatus 100 displays a wiring pattern in accordance with a mouse pointer, displays the later-placed component at a distal end of the wiring pattern, and may also display a “ratsnest” coincide with the component movement (S2202). The “ratsnest” is a bundle of virtual nets representing electrical connections between pins of components having connection relationships. The information processing apparatus 100 receives an instruction for a route for the wiring pattern (S2203).

Next, the information processing apparatus 100 obtains wire routing information from the mouse pointer (S2204). Subsequently, the information processing apparatus 100 obtains the occupied area of the wiring pattern at the corresponding position (S2205). Then, the information processing apparatus 100 obtains all adjacent elements from the obstacle management table 423 (S2206).

The information processing apparatus 100 determines whether or not there are any unselected adjacent elements (S2207). Upon determining that there are unselected adjacent elements (Yes in S2207), the information processing apparatus 100 selects one of the unselected adjacent elements (S2208). The information processing apparatus 100 then checks interference between the wiring pattern and the selected adjacent element by using the occupied areas (S2209).

The information processing apparatus 100 determines whether or not there is interference (S2210). Upon determining that there is no interference (No in S2210), the information processing apparatus 100 returns to S2207. Upon determining that there is interference (Yes in S2210), the information processing apparatus 100 displays an error (S2211). Subsequently, the information processing apparatus 100 sets an error flag (S2212) and then returns to S2207.

Upon determining that there is no more unselected adjacent element (No in S2207), the information processing apparatus 100 advances to S2301.

The information processing apparatus 100 determines whether or not an error flag is set (S2301). That is, the information processing apparatus 100 determines whether or not there is an interference error. Upon determining that no error flag is set (No in S2301), the information processing apparatus 100 finalizes the position of the route for the wiring pattern (S2302). The information processing apparatus 100 registers the wiring pattern in the obstacle management table 423 (S2303). The information processing apparatus 100 then determines whether or not the later-placed component is to be placed (S2304). Upon determining that the later-placed component is not to be placed (No in S2304), the information processing apparatus 100 advances to S2412. Upon determining that the later-placed component is to be placed (Yes in S2304), the information processing apparatus 100 receives an instruction for finalizing the placement of the later-placed component (S2305). The information processing apparatus 100 obtains position information of the later-placed component from the mouse pointer (S2306). Examples of the position information include information indicating a reference pin position, information indicating a placement surface, and information indicating a component rotation angle.

The information processing apparatus 100 determines the occupied area of the later-placed component when the later-placed component is placed at the corresponding position (S2307). The information processing apparatus 100 obtains all adjacent elements from the determined obstacle management table 423 on the basis of the determined occupied area of the later-placed component (S2308) and advances to S2401.

Upon determining that an error flag is set (Yes in S2301), the information processing apparatus 100 advances to S2412.

The information processing apparatus 100 determines whether or not there are any unselected adjacent elements (S2401). Upon determining that there are unselected adjacent elements (Yes in S2401), the information processing apparatus 100 selects one of the unselected adjacent elements (S2402). The information processing apparatus 100 obtains the occupied area of the selected adjacent element (S2403). The occupied areas of the already placed components are already set in S2102 illustrated in FIG. 21.

The information processing apparatus 100 refers to an occupied-area control table to check interference between the later-placed component to be placed and the occupied area of the adjacent element (S2404). The occupied-area control table has information that defines occupied areas of later-placed component and the adjacent element.

The information processing apparatus 100 determines whether or not there is interference (S2405). Upon determining that there is no interference (No in S2405), the information processing apparatus 100 returns to S2401. Upon determining that there is interference (Yes in S2405), the information processing apparatus 100 displays an error (S2406). In the error display in S2406, the information processing apparatus 100 displays, for example, the occupied area of the later-placed component in a highlighted manner. Next, the information processing apparatus 100 sets an error flag indicating that there is interference (S2407) and then returns to S2401.

Upon determining that there is no more adjacent element (No in S2401), the information processing apparatus 100 determines whether or not an error flag indicating that there is interference is set (S2408). Upon determining that no error flag is set (No in S2408), the information processing apparatus 100 finalizes the component placement and the wiring pattern (S2409). The information processing apparatus 100 then registers, in the obstacle management table 423, the later-placed component whose placement is finalized (S2410) and then advances to S2412.

Upon determining that an error flag is set (Yes in S2408), the information processing apparatus 100 recognizes that the component placement and the wiring pattern are not yet finalized and displays information indicating that the component placement and the wiring pattern are not yet finalized (S2411).

Next, the information processing apparatus 100 determines that the section wiring is completed (S2412). Upon determining that the section wiring is not completed (No in S2412), the information processing apparatus 100 advances to S2202. Upon determining that the section wiring is completed (Yes in S2412), the information processing apparatus 100 ends the series of processing.

As described above, during work on a wiring pattern for connecting an unplaced component from an already placed component on a board, when an unplaced component placed at the distal end of the wiring pattern and an already placed element do not interfere with each other, the information processing apparatus 100 finalizes the component placement and the wiring pattern. This makes it possible to perform the placement work while performing the wiring work, thus making it possible to improve the work efficiency of the placement and wiring. The improvement in the work efficiency means reduction of redoing of the placement work and the wiring work. Also, performing the placement work and the wiring work at the same time makes it possible to more easily perform individual work.

When there is interference, the information processing apparatus 100 displays information indicating that the placement of the first component is not permitted to be finalized at the position of the distal end of the wiring pattern and the first wiring pattern is not permitted to be finalized. This makes it possible to present information indicating that the unplaced component is not permitted to be placed at a position for which an instruction for the finalization is issued and makes it possible to facilitate the placement work and the wiring work.

The information processing apparatus 100 may display the first component in a state in which the first terminal is located at the distal end of the first wiring pattern and the first terminal and another terminal of the first component are located on the straight line of the first wiring pattern. This makes it possible to directly route a wiring pattern on a straight line from the center point of the body of the component toward the origin of the component lead. Thus, performing wiring work for a wiring pattern considering the orientation of a pin of an already placed component makes it possible to suppress generation of a pool of solder or the like and makes it possible to suppress a decline in the soldering quality.

Also, the information processing apparatus 100 may display the first component in a plurality of orientations in a state in which the first terminal is located at the position of the distal end of the first wiring pattern, and finalizes the placement of the first component in one of the plurality of orientations, which is designated by the designer. Thus, the component may be placed in an orientation considering the quality of soldering, among a plurality of orientations in which the component may be manufactured.

When a component whose terminals have a polarity, such as a two-terminal finite capacitor, is attached in a wrong direction during assembly, there is a possibility that a failure occurs in a product in which the component is mounted. During assembly, since components are mounted based on design information designed via CAD, no terminals are mounted in a wrong direction. However, for example, when a person removes a component owing to a product failure due to soldering or the like and then remounts the component or when a person remounts a component owing to a change in design, the component may be attached in a wrong direction.

Accordingly, the information processing apparatus 100 displays the first component in a plurality of orientations based on a polarity defined for the terminals of the first component and finalizes the placement of the first component in one of the plurality of orientations, which is designated by a designer. For example, in the case of a finite capacitor, the orientation of the finite capacitor is defined on a printed circuit board such that a terminal having a positive (+) polarity is placed in the positive direction on an X-axis or in the positive direction on a Y-axis. The orientation of the finite capacitor is defined on the printed circuit board such that a terminal having a negative (−) polarity is placed in the negative direction on the X-axis or in the negative direction on the Y-axis. In the case of a diode, the orientation of the diode is determined such that the anode terminal thereof is placed at the positive side on the X-axis or the positive side on the Y-axis. In the case of a diode, the orientation of the diode is determined such that the cathode terminal thereof is placed at the negative side on the X-axis or the negative side on the Y-axis. As described above, restricting the orientation of the placement of a component makes it possible to suppress the component being attached in a wrong direction. Accordingly, it is possible to perform design considering the manufacturability called DFM and testability called DFT.

Also, there a case in which the first component is already placed or is temporarily placed. When the first component is already placed, the information processing apparatus 100 does not display the first component in a state in which the first terminal is located on the second terminal of the second component, instead, moves the first component to the position of the distal end of the wiring pattern, finalizes the placement of the first component, and finalizes the wiring pattern. Thus, when the first component is already placed, component movement work may be performed while performing wiring work, thus making it possible to reduce redoing of the movement work and the wiring work.

When a second wiring pattern that connects from another terminal of the first component, which is different from the first terminal, to a terminal of a third component having a connection relationship with the other terminal is already finalized, the information processing apparatus 100 displays information indicating that the second wiring pattern is already finalized, before finalizing the placement of the first component. When another terminal is already wired, it is possible to provide the designer with information indicating that another terminal is already wired, thus making it possible to suppress unwanted movement of the component. Also, this allows the designer to select, for example, the placement of a component which reduces the length of a wiring pattern.

When the information processing apparatus 100 moves the first component to the position of the distal end of the wiring pattern, finalizes the placement of the first component, and finalizes the first wiring pattern, it removes the second wiring pattern and receives a designated route for the third wiring pattern that connects from another terminal to a terminal of the third component. This makes it possible to receive designation of a route for another wiring pattern in place of the removed wiring pattern, while moving the placement of the component.

A computer, such as a personal computer or a workstation, may execute a prepared component placement program to realize the component placement method described in the present embodiment. The component placement program is recorded in a computer-readable recording medium, such as a magnetic disk, an optical disk, a universal serial bus (USB) flash memory, and the computer reads the component placement program from the recording medium to execute it. The component placement program may also be distributed over a network, such as the Internet.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A non-transitory computer-readable recording medium having stored therein a program that causes a computer to execute a process, the process comprising:
displaying, when a first component is not yet placed on a printed circuit board to be designed in a simulation space, the first component in a first state in which a first terminal of the first component is located on a second terminal of a second component, the second terminal having a connection relationship with the first terminal, the second component being included in already placed components which are already placed on the printed circuit board;
displaying a first wiring pattern along a designated route, the first wiring pattern being to connect the second terminal to the first terminal;
re-displaying the first component in a state in which the first terminal is located at a first distal end of the first wiring pattern;
determining whether a pattern area of the first wiring pattern overlaps any of first areas of the already placed components or second areas of already wired wiring patterns;
determining, upon receiving an instruction for finalizing the designated route, whether a component area of the first component which is placed at a second distal end of the designated route overlaps any of the first areas or the second areas; and
finalizing placement of the first component at the second distal end and finalizing the first wiring pattern, when it is determined that the pattern area overlaps none of the first areas and the second areas and the component area overlaps none of the first areas and the second areas.

2. The non-transitory computer-readable recording medium according to claim 1, the process further comprising:
displaying first information when it is determined that the pattern area or the component area overlaps one of the first areas or one of the second areas, the first information indicating that finalization of the placement of the first component at the second distal end and finalization of the first wiring pattern are not possible.

3. The non-transitory computer-readable recording medium according to claim 1, the process further comprising:
displaying, when re-displaying the first component, the first component in a state in which the first terminal is located at the first distal end and the first terminal and another terminal of the first component are located on an extended straight line of the first wiring pattern.

4. The non-transitory computer-readable recording medium according to claim 1, the process further comprising:
displaying the first component in a plurality of orientations in a state in which the first terminal is located at the first distal end; and
determining whether the component area overlaps any of the first areas or the second area when the first component is placed at the second distal end in a designated orientation among the plurality of orientations.

5. The non-transitory computer-readable recording medium according to claim 4, wherein
the plurality of orientations are determined based on a polarity defined for the first terminal or another terminal of the first component.

6. The non-transitory computer-readable recording medium according to claim 1, the process further comprising:
displaying the first component and the already placed components such that the first component is distinguishable from the already placed components.

7. The non-transitory computer-readable recording medium according to claim 1, the process further comprising:
omitting, when the first component is already placed on the printed circuit board before the designated route is designated, the displaying of the first component in the first state;
moving the first component to the second distal end when it is determined that the pattern area overlaps none of the first areas and the second areas and the component area overlaps none of the first areas and the second areas; and
finalizing placement of the first component at the second distal end and finalizing the first wiring pattern.

8. The non-transitory computer-readable recording medium according to claim 7, the process further comprising:
displaying first information when a second wiring pattern is already finalized, the second wiring pattern connecting a third terminal of the first component to a fourth terminal of a third component, the third terminal being different from the first terminal, the fourth terminal having a connection relationship with the third terminal, the first information indicating that the second wiring pattern is already finalized.

9. The non-transitory computer-readable recording medium according to claim 8, the process further comprising:
removing the second wiring pattern when the first component is moved to the second distal end, the placement of the first component is finalized, and the first wiring pattern is finalized; and
receiving a designated route for a third wiring pattern that is to connect the third terminal to the fourth terminal.

10. A component placement method, comprising:
displaying by a computer, when a first component is not yet placed on a printed circuit board to be designed in a simulation space, the first component in a first state in which a first terminal of the first component is located on a second terminal of a second component, the second terminal having a connection relationship with the first terminal, the second component being included in already placed components which are already placed on the printed circuit board;
displaying a first wiring pattern along a designated route, the first wiring pattern being to connect the second terminal to the first terminal;
re-displaying the first component in a state in which the first terminal is located at a first distal end of the first wiring pattern;
determining whether a pattern area of the first wiring pattern overlaps any of first areas of the already placed components or second areas of already wired wiring patterns;
determining, upon receiving an instruction for finalizing the designated route, whether a component area of the first component which is placed at a second distal end of the designated route overlaps any of the first areas or the second areas; and
finalizing placement of the first component at the second distal end and finalizing the first wiring pattern, when it is determined that the pattern area overlaps none of the first areas and the second areas and the component area overlaps none of the first areas and the second areas.

11. An information processing apparatus, comprising:
a memory; and
a processor coupled to the memory and the processor configured to
display, when a first component is not yet placed on a printed circuit board to be designed in a simulation space, the first component in a first state in which a first terminal of the first component is located on a second terminal of a second component, the second terminal having a connection relationship with the first terminal, the second component being included in already placed components which are already placed on the printed circuit board,
display a first wiring pattern along a designated route, the first wiring pattern being to connect the second terminal to the first terminal,
re-display the first component in a state in which the first terminal is located at a first distal end of the first wiring pattern,
determine whether a pattern area of the first wiring pattern overlaps any of first areas of the already placed components or second areas of already wired wiring patterns,
determine, upon receiving an instruction for finalizing the designated route, whether a component area of the first component which is placed at a second distal end of the designated route overlaps any of the first areas or the second areas, and
finalize placement of the first component at the second distal end and finalizing the first wiring pattern, when it is determined that the pattern area overlaps none of the first areas and the second areas and the component area overlaps none of the first areas and the second areas.
